(19) United States
(12) Patent Application Publication
(10) Pub. No.: US 2025/0062257 A1
(43) Pub. Date: Feb. 20, 2025

(54) SEMICONDUCTOR CHIP AND SEMICONDUCTOR PACKAGE INCLUDING THE SAME

(71) Applicant: Samsung Electronics Co., Ltd., Suwon-si (KR)

(72) Inventors: Young-Deuk KIM, Suwon-si (KR); Heejung HWANG, Suwon-si (KR)

(73) Assignee: Samsung Electronics Co., Ltd., Suwon-si (KR)

(21) Appl. No.: 18/435,016

(22) Filed: Feb. 7, 2024

(30) Foreign Application Priority Data
Aug. 17, 2023 (KR) 10-2023-0107504

(51) Int. Cl. H01L 23/00; H01L 23/31; H01L 23/36; H01L 23/48; H01L 25/065; H10B 80/00

(52) U.S. Cl. CPC H01L 24/06; H01L 23/3107; H01L 23/36; H01L 23/481; H01L 24/05; H01L 24/16; H01L 25/0657; H10B 80/00; H01L 2224/05; H01L 2224/06519; H01L 2224/16145

(57) ABSTRACT

A semiconductor chip including a body that having a front surface and a rear surface; a wiring structure above the front surface of the body; a through via penetrating the body, and the through via is connected to the wiring structure; a heat dissipation structure above the rear surface of the body, and the heat dissipation structure includes a conductive layer connected to the through via; and a signal pad and a heat dissipation pad on the heat dissipation structure, and the signal pad and the heat dissipation pad are connected to the conductive layer.

### CROSS-REFERENCE TO RELATED APPLICATION

This application claims priority under 35 U.S.C. § 119 to Korean Patent Application No. 10-2023-0107504 filed at the Korean Intellectual Property Office on Aug. 17, 2023, the entire contents of which are incorporated herein by reference.

### BACKGROUND

The present disclosure relates to a semiconductor chip and a semiconductor package including the same.

In the semiconductor industry, high bandwidth memory (HBM) that may provide expanded memory capacity and high bandwidth by stacking a plurality of dynamic random access memories (DRAMs) on a memory controller chip is widely used.

Because high bandwidth memory includes a plurality of DRAMs, it generates more heat while consuming more electric power. If heat generated from each DRAM is not efficiently dissipated, problems such as reduced performance and reliability of the high bandwidth memory, reduced power efficiency due to an increase in internal resistance, and shortened lifespan may occur.

Therefore, semiconductor chips and/or semiconductor package structures that efficiently dissipate heat generated from semiconductor chips (e.g., high bandwidth memory DRAM) that generate a lot of heat, are required.

### SUMMARY

Example embodiments of the inventive concepts provide a semiconductor chip with excellent heat dissipation characteristics and a semiconductor package including the same.

Example embodiments of the inventive concepts provide a semiconductor chip including a body having a front surface and a rear surface; a wiring structure above the front surface of the body; a through via penetrating the body, and the through via being connected to the wiring structure; a heat dissipation structure above the rear surface of the body, and the heat dissipation structure including a conductive layer connected to the through via; and a signal pad and at least one heat dissipation pad on the heat dissipation structure, and the signal pad and the at least one heat dissipation pad being connected to the conductive layer. The signal pad may include at least one of a power pad and a ground pad. The conductive layer may include a metal layer. A thickness of the conductive layer may be 3 to 5 μm. The conductive layer may include a conductive pattern that overlaps the signal pad, the at least one heat dissipation pad, and the through via on a plane. The heat dissipation structure may further include an insulating layer covering the conductive layer, and vias penetrating the insulating layer to connect the conductive layer to the signal pad and the heat dissipation pad respectively. The insulating layer may include at least one of silicon oxide and silicon nitride. A thickness of the insulating layer may be 3.5 to 6 μm. A diameter of the vias may be 3 to 10 μm. The semiconductor chip may further include an insulating layer between the body and the conductive layer. The insulating layer may be on the body and may include a first insulating layer including silicon oxide, and a second insulating layer between the first insulating layer and the heat dissipation structure and including silicon nitride. The semiconductor chip may include a memory chip. The at least one heat dissipation pad may include a plurality of heat dissipation pads spaced apart from each other.

Example embodiments of the inventive concepts may further provide a semiconductor package including a first semiconductor chip; and a plurality of second semiconductor chips stacked on the first semiconductor chip. Each of the plurality of second semiconductor chips includes a body having a front surface and a rear surface; a wiring structure above the front surface of the body; a through via penetrating the body, and the through via being connected to the wiring structure; a heat dissipation structure above the rear surface of the body, and the heat dissipation structure including a conductive layer connected to the through via; and a signal pad and a heat dissipation pad on the heat dissipation structure, and the signal pad and the heat dissipation pad being connected to the conductive layer, the first semiconductor chip includes a memory controller chip, and the second semiconductor chip includes a memory chip. The signal pad may include at least one of a power pad and a ground pad. The conductive layer may include a conductive pattern that overlaps the signal pad, the heat dissipation pad, and the through via on a plane. The heat dissipation structure may further include an insulating layer covering the conductive layer, and vias penetrating the insulating layer to connect the conductive layer to the signal pad and the heat dissipation pad respectively. The semiconductor package may further include conductive bumps on the signal pad and the heat dissipation pad of each of the plurality of second semiconductor chips to connect the plurality of second semiconductor chips to each other. The semiconductor package may further include an encapsulant encapsulating the plurality of second semiconductor chips.

Example embodiments of the inventive concepts may still further provide a semiconductor package including a first semiconductor chip; and a second semiconductor chip on the first semiconductor chip. The first semiconductor chip includes a body having a front surface and a rear surface; a wiring structure above the front surface of the body; a through via penetrating the body, and the through via being connected to the wiring structure; a heat dissipation structure above the rear surface of the body, and the heat dissipation structure including a conductive layer connected to the through via; and a signal pad and a heat dissipation pad on the heat dissipation structure, and the signal pad and the heat dissipation pad being connected to the conductive layer.

### BRIEF DESCRIPTION OF THE DRAWINGS

FIG. 1 is a cross-sectional view of a semiconductor chip according to some example embodiments of the inventive concepts.

FIG. 2 is a cut plan view of the semiconductor chip of FIG. 1 cut along a line A-A′.

FIG. 3 is a cross-sectional view of the semiconductor package according to some example embodiments of the inventive concepts.

FIG. 4 is a cross-sectional view of a semiconductor package according to some other example embodiments of the inventive concepts.

FIG. 5 is a cross-sectional view of a package including the semiconductor package according to some example embodiments of the inventive concepts.

FIGS. 6A, 6B, 6C, 6D, 6E, 6F, 6G and 6H are manufacturing process views of the semiconductor chip according to some example embodiments of the inventive concepts.

### DETAILED DESCRIPTION

The present disclosure will be described more fully hereinafter with reference to the accompanying drawings. In the drawings, the size and thickness of each element are arbitrarily illustrated for ease of description, and the inventive concepts are not necessarily limited to those illustrated in the drawings. In the drawings, the thicknesses of layers, films, panels, regions, areas, etc., may be exaggerated for clarity and/or ease of description.

Throughout the specification, when a part is described as “connected” to another part, it includes not only the part being “directly connected” but also the part being “indirectly connected” with another part in between. In a similar sense, this includes being “physically connected” as well as being “electrically connected”. Unless explicitly described to the contrary, the word “comprise” and variations such as “comprises” or “comprising” will be understood to imply the inclusion of stated elements but not the exclusion of any other elements.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout the specification, sequential numbers such as 1st and 2nd are used to distinguish a certain component from another component that is the same or similar, and are not necessarily intended to refer to a specific component. Accordingly, a component referred to as a first component in a specific portion of the specification may be referred to as a second component in another portion of the specification.

Throughout the specification, a singular reference to a component includes references to a plurality of these components, unless specifically stated to the contrary. For example, “an insulating layer” may be used to mean not only one insulating layer but also a plurality of insulating layers such as two, three, or more insulating layers.

Throughout the specification, references to one surface and the other surface are intended to distinguish different surfaces from each other, and are not necessarily intended to limit it to a specific surface. Accordingly, a surface referred to as one surface in a specific portion of the specification may be referred to as the other surface in another portion of the specification.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, a semiconductor chip and a semiconductor package according to some example embodiments of the inventive concepts will be described with reference to the drawings.

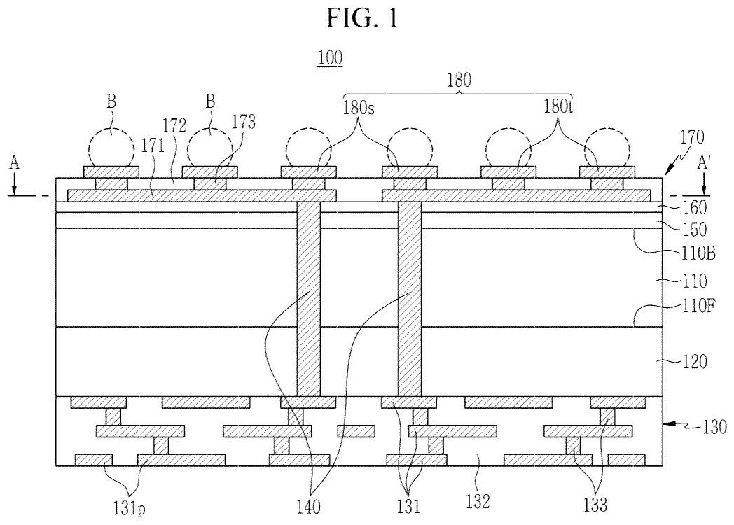

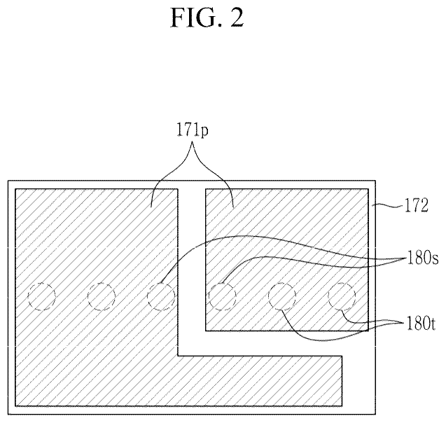

Referring to FIG. 1 and FIG. 2, the semiconductor chip 100 may include a body 110 having a front surface 110F and a rear surface (or a back surface) 110B, an element layer 120 and a wiring structure 130 disposed above or on the front surface 110F of the body 110, a through via (or a penetrating via) 140 penetrating the body 110, insulating layers 150 and 160 disposed above or on the rear surface 110B of the body, a heat dissipation structure 170, and a pad 180.

When another semiconductor chip is disposed above or on the semiconductor chip 100, a conductive bump B for connection between the two semiconductor chips may be disposed on the pad 180.

The body 110 may be a semiconductor wafer. The body 110 may include silicon (Si). Alternatively, the body 110 may include a compound such as gallium arsenide (GaAs), silicon carbide (SiC), or the like. The body 110 may include a conductive region such as an impurity-doped well.

The element layer 120 may include a plurality of various types of individual devices (individual elements) and an interlayer insulating film. The plurality of individual devices may include metal-oxide-semiconductor field-effect transistors (MOSFET), system large scale integration (LSI), image sensors such as CMOS imaging sensors (CIS), active elements, passive elements, or the like. The element layer 120 may be referred to as a front-end-of-line (FEOL).

The wiring structure 130 may be disposed on the element layer 120, and may include a wiring layer 131, an insulating layer 132, and a via 133. The number of layers of the wiring structure 130 is not particularly limited, and may be more or less than that illustrated in the drawings. The wiring structure 130 may be referred to as a back-end-of-line (BEOL).

The wiring layer 131 may be physically and/or electrically connected to the through via 140. Depending on a method of forming the through via 140, the wiring layer 131 may be directly connected to the through via 140, or may be indirectly connected to the through via 140 through the element layer 120.

Additionally, the wiring layer 131 may include a connection pad 131p for electrically connecting the semiconductor chip 100 to another component (e.g., another semiconductor chip, a substrate, or the like) other than the semiconductor chip 100. A conductive bump may be disposed on the connection pad 131p, and the semiconductor chip 100 may be physically and/or electrically connected to the other component through the conductive bump.

A conductive material may be used as a material of the wiring layer 131, and for example, the wiring layer 131 may include aluminum (Al), copper (Cu), gold (Au), silver (Ag), platinum (Pt), tin (Sn), chromium (Cr), palladium (Pd), lead (Pb), titanium (Ti), or an alloy thereof.

The insulating layer 132 may be disposed between wiring layers 131 to bury the wiring layers 131, and may insulate the wiring layers 131 from each other.

An insulating material may be used as a material of the insulating layer 132, and for example, the insulating layer 132 may include silicon oxide, silicon nitride, or the like.

The via 133 may penetrate the insulating layer 132 and connect the wiring layers 131 disposed in different layers to each other.

The via 133 may have a circular cylinder shape or a tapered shape whose diameter narrows in a direction from one surface to the other surface.

A formation material of the via 133 may be the same as a formation material of the wiring layer 131. The via 133 may be integrally formed with the wiring layer 131, and in some example embodiments, there is no boundary between the wiring layer 131 and the via 133.

The through via 140 may be connected to the wiring structure 130 and a conductive layer 171, and may connect them to each other. For example, one end of the through via 140 may be connected to the wiring structure 130, and the other end of the through via 140 may be connected to the conductive layer 171. The through via 140 may be directly connected to the wiring structure 130, or may be indirectly connected to the wiring structure 130 through the element layer 120. A configuration of the wiring structure 130 electrically connected to the through via 140 may be the wiring layer 131. Additionally, the through via 140 may be connected to a signal pad 180s and at least one heat dissipation pad 180t through the conductive layer 171.

The through via 140 may transfer a signal in a thickness direction of the semiconductor chip 100. A signal that is generated in the semiconductor chip 100 or that is transferred to the semiconductor chip 100 may be transferred to the conductive layer 171 and the signal pad 180s through the through via 140. The transferred signal may be transferred to another configuration outside the semiconductor chip 100 that is connected to the signal pad 180s.

The through via 140 may transfer heat in the thickness direction of the semiconductor chip 100. Heat generated from the semiconductor chip 100 may be transferred to the conductive layer 171 and the heat dissipation pad 180t through the through via 140. The transferred heat may be emitted to the outside of the semiconductor chip 100 through the heat dissipation pad 180t and the conductive bump B connected to the heat dissipation pad 180t.

A via-first method, a via-middle method, or a via-last method may be used as a method of forming the through via 140. Depending on the method of forming the through via 140, a region of the semiconductor chip 100 that the through via 140 penetrates may change, and is not limited to a region shown in the drawings. In some example embodiments, the through via 140 may penetrate only the body 110, and may not penetrate the element layer 120 and the wiring structure 130. In some other example embodiments, the through via 140 may penetrate all of the body 110, the element layer 120, and the wiring structure 130. in some other example embodiments, the through via 140 may penetrate the body 110 and the element layer 120, and may penetrate only a portion of the wiring structure 130 in a thickness direction.

The through via 140 may include a pillar-shaped conductive plug and a conductive barrier film surrounding the conductive plug. A conductive material may be used as a material of each of the conductive plug and the conductive barrier film. For example, the material of the conductive plug may include tungsten (W), copper (Cu), aluminum (Al), nickel (Ni); an alloy of tungsten (W), copper (Cu), aluminum (Al), and nickel (Ni); doped polysilicon; or the like. Additionally, titanium (Ti), titanium nitride (TiN), tantalum (Ta), tantalum nitride (TaN), or the like may be used as the material of the conductive barrier film.

Any one of a physical vapor deposition (PVD) process, a chemical vapor deposition (CVD) process, an atomic layer deposition (ALD) process, an electroless plating process, and an electrolytic plating process, or a combination of two or more thereof may be used as a method of forming the through via 140.

An insulating film (not shown) may be disposed between the conductive barrier film of the through via 140 and the body 110. The insulating film may include silicon oxide, silicon nitride, an insulating resin, or a combination thereof.

The insulating layers 150 and 160 may be disposed between the body 110 and the conductive layer 171. The insulating layers 150 and 160 may be a plurality of insulating layers, and may include, for example, the first insulating layer 150 and the second insulating layer 160.

The first insulating layer 150 may be disposed on the body 110. The first insulating layer 150 may physically, mechanically, and chemically protect the body 110, and may insulate the body 110 from the conductive layer 171. The first insulating layer 150 may include silicon oxide.

The second insulating layer 160 may be disposed on the first insulating layer 150, and for example, may be disposed between the first insulating layer 150 and the heat dissipation structure 170. The second insulating layer 160 may protect the body 110 together with the first insulating layer 150, may insulate the body 110 from the conductive layer 171, and may serve to limit and/or prevent mechanical peeling of the conductive layer 171. The second insulating layer 160 may include silicon nitride, and may have an excellent insulation property, an excellent mechanical strength, and an excellent chemical stability.

The through via 140 may penetrate the body 110, and may further penetrate the insulating layers 150 and 160 to be connected to the conductive layer 171. The through via 140 may integrally penetrate the body 110 and the insulating layers 150 and 160. Alternatively, the through via 140 may have a boundary between a region penetrating the body 110 and a region penetrating the insulating layers 150 and 160.

In some example embodiments, the semiconductor chip 100 may not include at least one of the first insulating layer 150 and the second insulating layer 160.

The heat dissipation structure 170 may include the conductive layer 171 connected to the through via 140, and may further include an insulating layer 172 and vias 173.

The heat dissipation structure 170 is shown as including only a single conductive layer 171 and a single insulating layer 172. However, in some other example embodiments the heat dissipation structure 170 may include a plurality of conductive layers 171 and/or a plurality of insulating layers 172. However, to reduce a thickness of the semiconductor chip 100, a single heat dissipation structure 170 may include only the single conductive layer 171 and the single insulating layer 172.

The conductive layer 171 may be connected to the through via 140, the signal pad 180s, and the heat dissipation pad 180t.

In terms of signal transfer, the conductive layer 171 may connect the through via 140 and the signal pad 180s and may transfer a signal transferred from the through via 140 to the signal pad 180s. Accordingly, the transferred signal may be transferred to another configuration outside the semiconductor chip 100 that is connected to the signal pad of the semiconductor chip 100 through the signal pad 180s. Some of heat generated in the semiconductor chip 100 may be transferred to the signal pad 180s through the conductive layer 171 to be emitted to the outside of the semiconductor chip 100 through the signal pad 180s.

In terms of heat transfer, the conductive layer 171 may connect the through via 140 and the heat dissipation pad 180t. Therefore, the heat generated in the semiconductor chip 100 may be emitted to the outside of the semiconductor chip 100 via the through via 140, the conductive layer 171, the heat dissipation pad 180t, and the conductive bump B connected to the heat dissipation pad 180t. For example, the through via 140, the conductive layer 171, and the heat dissipation pad 180t may be connected to each other to form a heat dissipation path of the semiconductor chip 100.

Referring to FIG. 2, the conductive layer 171 may include a conductive pattern 171p overlapping the signal pad 180s, the heat dissipation pad 180t, and the through via 140 on a plane. Because heat is transferred through the conductive pattern 171p that has a line width much larger than that of a typical wiring pattern, the semiconductor chip 100 may have an excellent heat dissipation effect.

FIG. 2 shows only the signal pad 180s and the heat dissipation pad 180t shown in a cross-section of FIG. 1. In some example embodiments a greater number of signal pads 180s and heat dissipation pads 180t than the number of the signal pads 180s and the heat dissipation pads 180t shown in FIG. 2 may be disposed above the conductive layer 171.

The conductive layer 171 may be a layer including a material with high thermal conductivity, and may be a metal layer. The metal layer may include aluminum (Al), copper (Cu), gold (Au), silver (Ag), platinum (Pt), tin (Sn), chromium (Cr), palladium (Pd), lead (Pb), titanium (Ti), or an alloy thereof.

A thickness of the conductive layer 171 may be about 3 to 5 μm. If the thickness of the conductive layer 171 is too small, a heat conduction effect may be insignificant, and if the thickness of the conductive layer 171 is too large, it may be difficult to thin the package. Thus, the thickness of the conductive layer 171 may be adjusted within the above-described range.

The insulating layer 172 may cover the conductive layer 171, and may physically, mechanically, and chemically protect the conductive layer 171. In some example embodiments the insulating layer 172 may include at least one of silicon oxide and silicon nitride, and an increase in thermal resistance of the semiconductor chip 100 may be reduced (and/or minimized). However, the inventive concepts are not limited thereto, and the insulating layer 172 may include another material (an epoxy resin, a polyimide resin, or the like) that has an insulation property while having excellent bonding force with the insulating layers 150 and 160 or the body 110 that are coupled to the insulating layer 172.

A thickness of the insulating layer 172 may be about 3.5 to 6 μm. If the thickness of the insulating layer 172 is too small, a protective effect provided to the conductive layer 171 may be insignificant, and if the thickness of the insulating layer 172 is too large, it may be difficult to thin the package. Thus, the thickness of the insulating layer 172 may be adjusted within the above-described range.

The vias 173 may penetrate the insulating layer 172 to connect the conductive layer 171 to the signal pad 180s and the heat dissipation pad 180t respectively.

The via 173 may have a circular cylinder shape or a tapered shape whose diameter narrows in a direction from one surface to the other surface. For example, the via 173 may have a tapered shape whose diameter narrows in a direction from the pad 180 to the conductive layer 171.

The via 173 may include a material with high thermal conductivity, and a material of the via 173 may be the same as a formation material of the conductive layer 171.

The via 173 may have a relatively large diameter for a heat dissipation characteristic. For example, a diameter of the via 173 may be about 3 to 10 μm. If the diameter of the via 173 is too small, a heat dissipation effect may be insignificant, and if the diameter of the via 173 is too large, heat dissipation through the via 173 may be difficult. Thus, the diameter of the via 173 may be adjusted within the above-described range.

The diameter of the via 173 may be larger than a diameter of the through via 140 and/or a diameter of the via 133 of the wiring structure 130, but the inventive concepts are not limited thereto. In some example embodiments, the diameter of the via 173 may be smaller than the diameter of the through via 140 or may be the same as the diameter of the through via 140. In some example embodiments, the diameter of the via 173 may be smaller than or equal to the diameter of the via 133 of the wiring structure 130. In some example embodiments, the diameter of the via 173 connected to the heat dissipation pad 180t may be larger than the diameter of the via 173 connected to the signal pad 180s, but in some other example embodiments the diameter of the via 173 connected to the heat dissipation pad 180t may be the same as the diameter of the via 173 connected to the signal pad 180s or may be smaller than the diameter of the via 173 connected to the signal pad 180s.

The pad 180 may include the signal pad 180s and the heat dissipation pad 180t connected to the conductive layer 171. The signal pad 180s and the heat dissipation pad 180t may be disposed at the same level. The signal pad 180s may include a plurality of signal pads 180s spaced apart from each other. Similarly, the at least one heat dissipation pad 180t may include a plurality of heat dissipation pads 180t spaced apart from each other. The signal pad 180s and the heat dissipation pad 180t may be disposed to be spaced apart from each other. The signal pad 180s and the heat dissipation pad 180t, the plurality of signal pads 180s, or the plurality of heat dissipation pads 180t may be disposed at regular pitch intervals.

The signal pad 180s may include at least one of a power pad and a ground pad. Because the through via 140 is connected not only to the signal pad 180s but also to the heat dissipation pad 180t, the signal pad 180s may include at least one of the power pad and the ground pad in order to maintain a signal quality of the semiconductor chip 100 and reduce and/or prevent a possibility of an electric short. The signal pad 180s may include only the power pad and/or the ground pad. From a similar perspective, the signal pad 180s connected to the conductive layer 171 may not include a data pad, a clock pad, a sensor pad, or the like. However, in some example embodiments, the signal pad 180s may include a signal pad other than the power pad and the ground pad.

A conductive material may be used as a material of the pad 180, and for example, the pad 180 may include aluminum (Al), copper (Cu), gold (Au), silver (Ag), platinum (Pt), tin (Sn), chromium (Cr), palladium (Pd), lead (Pb), titanium (Ti), or an alloy thereof.

The pad 180 may be integrally formed with the via 173, and a boundary between the pad 180 and the via 173 may not exist. However, the inventive concepts are not limited thereto, and in some example embodiments the pad 180 may be separately formed from the via 173 so that the boundary between the pad 180 and the via 173 exists.

The semiconductor chip 100 may further include a passivation layer (not shown) disposed on the heat dissipation structure 170 and having an opening exposing the pad 180.

The semiconductor chip 100 may be a memory chip. In some example embodiments, the memory chip may be a high bandwidth memory (HBM) DRAM. In a high bandwidth memory (HBM) structure in which a plurality of high bandwidth memory DRAMs are stacked, heat generated from each DRAM may be emitted in an upward direction where the through via 140, the conductive layer 171, and the heat dissipation pad 180t are stacked through the heat dissipation path including the through via 140, the conductive layer 171, and the heat dissipation pad 180t. However, the semiconductor chip 100 is not limited to a memory chip such as the high bandwidth memory DRAM, and in some example embodiments the semiconductor chip 100 may include a different type of chip such as a logic chip, a processor chip such as a central processing unit (CPU) or a graphics processing unit (GPU), a sensor chip, a system on chip (SOC), or the like.

On the other hand, to dissipate heat generated from the semiconductor chip, a heat dissipation pad may be disposed above or on the body of the semiconductor chip along with a signal pad connected to a through via. An insulating layer such as a silicon oxide film or the like may be disposed between the body of the semiconductor chip and the heat dissipation pad for purposes of protection of the body, electrical insulation, and the like. However, in such a structure or configuration, one surface of the heat dissipation pad may contact the insulating layer such as the silicon oxide film so that heat is not efficiently transferred from the semiconductor chip and a thermal bottleneck phenomenon occurs.

In the semiconductor chip 100 according to some example embodiments of the inventive concepts, the heat dissipation structure 170 including the conductive layer 171 connected to the through via 140, may be disposed between the body 110 and the pad 180 of the semiconductor chip 100. Thus, heat generated in the semiconductor chip 100 may be efficiently dissipated to the outside of the semiconductor chip 100 along the heat dissipation path including the through via 140, the conductive layer 171, and the heat dissipation pad 180t, and a thermal bottleneck phenomenon may be reduced and/or prevented. It may be confirmed that in an 8-stack high bandwidth memory (HBM) structure including the heat dissipation structure 170 according to some example embodiments of the inventive concepts, thermal conductivity of about 4.54 W/mK may be achieved, which is an increase of about 37% compared with thermal conductivity of 3.31 W/mK of a corresponding structure not including heat dissipation structure 170.

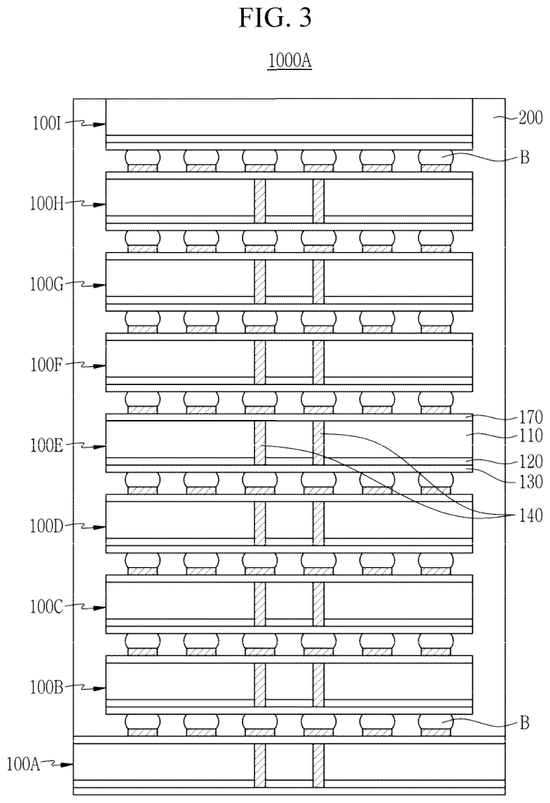

Referring to FIG. 3, a semiconductor package 1000A according to some example embodiments may include a plurality of semiconductor chips 100A-1001. For example, as shown in the drawings, the semiconductor package 1000A may include the first semiconductor chip 100A and the plurality of second semiconductor chips 100B-1001 disposed above or on the first semiconductor chip 100A.

The semiconductor package 1000A may be a high bandwidth memory package, the first semiconductor chip 100A may be a memory controller chip, and each of the second semiconductor chips 100B-1001 may be a memory chip. The memory controller chip may be referred to as a master chip, a buffer chip, a logic chip, a base chip, an interface chip, or the like, and the memory chip disposed above or on the memory controller chip may be referred to as a slave chip, a core chip, or the like.

Each of the plurality of second semiconductor chips 100B-1001 may be the semiconductor chip 100 according to some example embodiments described with respect to FIGS. 1 and 2. Therefore, each of the plurality of second semiconductor chips 100B-1001 may include the body 110 having the front surface 110F and the rear surface (or the back surface) 110B, the element layer 120 and the wiring structure 130 disposed above or on the front surface 110F of the body 110, the through via (or the penetrating via) 140 penetrating the body 110, the insulating layers 150 and 160 disposed above or on the rear surface 110B of the body, the heat dissipation structure 170, and the pad 180. Because description of the configuration of second semiconductor chips 100B-1001 is the same as the previous description, further detailed description thereof is omitted.

However, as shown in FIG. 3, the second semiconductor chip 1001 disposed at an uppermost side among the plurality of second semiconductor chips 100B-1001 may not include the through via 140, the heat dissipation structure 170 including the conductive layer 171, and the pad 180. However, in some other example embodiments, if necessary the second semiconductor chip 1001 disposed at the uppermost side may include some or all of the through via 140, the heat dissipation structure 170 including the conductive layer 171, and the pad 180.

In some example embodiments, the first semiconductor chip 100A may be the semiconductor chip 100. Therefore, the first semiconductor chip 100A may also include the body 110 having the front surface 110F and the rear surface (or the back surface) 110B, the element layer 120 and the wiring structure 130 disposed above or on the front surface 110F of the body 110, the through via (or the penetrating via) 140 penetrating the body 110, the insulating layers 150 and 160 disposed above or on the rear surface 110B of the body, the heat dissipation structure 170, and the pad 180. Because description of the configuration of first semiconductor chip 100A is the same as previous description of semiconductor chip 100, further detailed description is be omitted.

In some example embodiments including the first semiconductor chip 100A configured as the semiconductor chip 100 along with the plurality of second semiconductor chips 100B-1001, heat generated from the first semiconductor chip 100A may also be emitted in an upward direction via the through via 140, the conductive layer 171, and the heat dissipation pad 180t.

The semiconductor package 1000A may include the plurality of semiconductor chips 100A-1001, and may include the conductive bump B connecting the plurality of semiconductor chips 100A-1001 to each other.

The conductive bump B may be disposed on the signal pad 180s and the heat dissipation pad 180t of each of the plurality of second semiconductor chips 100B-1001 to include the conductive bump B connecting the plurality of second semiconductor chips 100B-1001 to each other. The conductive bump B that connects the plurality of second semiconductor chips 100B-1001 to each other may be connected to the connection pad 131p of the second semiconductor chip disposed at an upper side of the conductive bump B.

The conductive bump B may be disposed on the signal pad 180s and the heat dissipation pad 180t of the first semiconductor chip 100A to connect the first semiconductor chip 100A and the second semiconductor chip 100B to each other. The conductive bump B that connects the first semiconductor chip 100A and the second semiconductor chip 100B may be connected to the connection pad 131p of the second semiconductor chip 100B.

Copper (Cu), palladium (Pd), bismuth (Bi), antimony (Sb), tin (Sn), silver (Ag), an alloy thereof such as a tin-silver (SnAg) alloy may be used as a material of the conductive bump B. For example, the conductive bump B may be a solder ball.

The semiconductor package 1000A may further include an encapsulant 200. As shown in FIG. 3, the encapsulant 200 may be disposed on the first semiconductor chip 100A to encapsulate the plurality of second semiconductor chips 100B-1001. However, the inventive concepts are not limited thereto, and in some other example embodiments in which the first semiconductor chip 100A is disposed on a substrate (not shown), the encapsulant 200 may be disposed on the substrate to further encapsulate the first semiconductor chip 100A together with the plurality of second semiconductor chips 100B-1001.

A thermosetting resin such as an epoxy resin, an epoxy molding compound (EMC), or the like may be used as a material of the encapsulant 200. A process of molding the plurality of second semiconductor chips 100B-1001 with the encapsulant 200 may be performed by compression molding, transfer molding, or the like.

A conductive bump (not shown) for connecting the semiconductor package 1000A to another component such as a substrate or the like may be additionally disposed on the wiring structure 130 of the first semiconductor chip 100A.

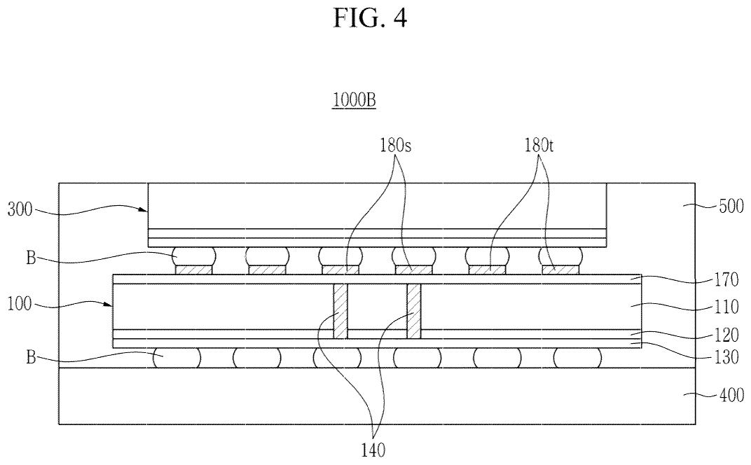

Referring to FIG. 4, a semiconductor package 1000B according to some example embodiments may include a first semiconductor chip 100 and a second semiconductor chip 300 disposed above or on the first semiconductor chip 100. For example, the semiconductor package 1000B may be a semiconductor package having a three-dimensional integrated circuit (3D-IC) structure (or a three-dimensional integrated die structure) in which the first semiconductor chip 100 and the second semiconductor chip 300 are stacked in a vertical direction to be connected to each other through the through via 140 of the first semiconductor chip 100.

According to some example embodiments, the first semiconductor chip 100 may be the semiconductor chip 100. Therefore, the first semiconductor chip 100 may include the body 110 having the front surface 110F and the rear surface (or the back surface) 110B, the element layer 120 and the wiring structure 130 disposed above or on the front surface 110F of the body 110, the through via (or the penetrating via) 140 penetrating the body 110, the insulating layers 150 and 160 disposed above or on the rear surface 110B of the body, the heat dissipation structure 170, and the pad 180. Because description of the configuration of the first semiconductor chip 100 of FIG. 4 is the same as described with respect to FIGS. 1 and 2, further detailed description thereof is omitted.

According to some example embodiments, the second semiconductor chip 300 may also be configured as the semiconductor chip 100.

Second semiconductor chip 300 is not limited to any particular type of chip, and in some example embodiments the second semiconductor chip 300 may include a memory chip, a logic chip, a processor chip such as a central processing unit (CPU) or a graphics processing unit (GPU), a sensor chip, a system on chip (SOC), or the like.

The semiconductor package 1000B may include the first semiconductor chip 100 and the second semiconductor chip 300, the conductive bump B connecting the first semiconductor chip 100 and the second semiconductor chip 300 to each other. The conductive bump B may be disposed on the signal pad 180s and the heat dissipation pad 180t of the first semiconductor chip 100 so that the first semiconductor chip 100 and the second semiconductor chip 300 are connected to each other. Description of the configuration of conductive bump B is the same as the previous description.

The semiconductor package 1000B may further include a substrate 400 at which the first semiconductor chip 100 and the second semiconductor chip 300 are disposed, and an encapsulant 500 disposed on the substrate 400 to encapsulate the first semiconductor chip 100 and the second semiconductor chip 300.

The substrate 400 may be any substrate generally used in semiconductor packaging. The substrate 400 may include an insulating layer and a wiring layer. A conductive bump B may be disposed between the first semiconductor chip 100 and the substrate 400 to connect the first semiconductor chip 100 and the substrate 400 to each other. Description of the configuration of conductive bump B is the same as the previous description. A conductive bump (not shown) for connecting the semiconductor package 1000B to another component may be additionally disposed on a lower surface of the substrate 400.

A thermosetting resin such as an epoxy resin, an epoxy molding compound (EMC), or the like may be used as a material of the encapsulant 500. A process of molding the first semiconductor chip 100 and the second semiconductor chip 300 with the encapsulant 500 may be performed by compression molding, transfer molding, or the like.

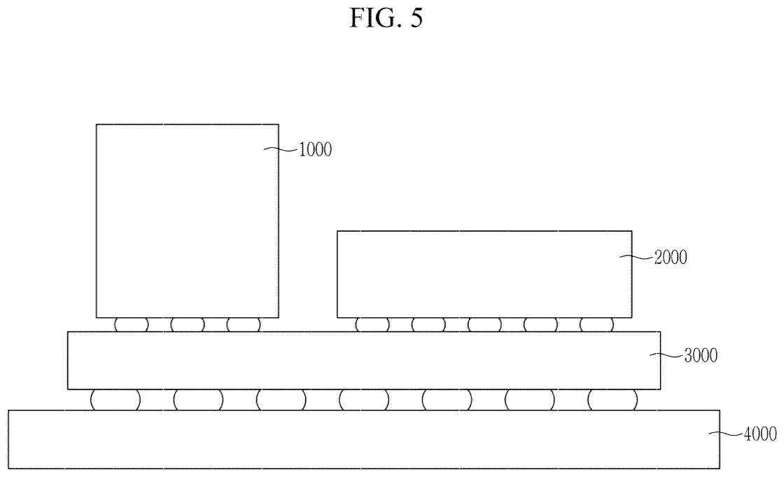

Referring to FIG. 5, a package according to some example embodiments of the inventive concepts may include the semiconductor package 1000, a semiconductor chip 2000, an interposer substrate 3000, and a package substrate 4000.

The semiconductor package 1000 may be the semiconductor package 1000A or 1000B respectively shown and described with respect to FIGS. 3 and 4. Therefore, the semiconductor package 1000 may include the semiconductor chip 100 such as shown in FIG. 1 including the body 110 having the front surface 110F and the rear surface (or the back surface) 110B, the element layer 120 and the wiring structure 130 disposed above or on the front surface 110F of the body 110, the through via (or the penetrating via) 140 penetrating the body 110, the insulating layers 150 and 160 disposed above or on the rear surface 110B of the body, the heat dissipation structure 170, and the pad 180. Because description of the configuration of the semiconductor chip of semiconductor package 1000 in FIG. 5 is the same as the previous description, further detailed description thereof is omitted.

The semiconductor chip 2000 may be disposed side by side with the semiconductor package 1000 above or on the interposer substrate 3000.

Second semiconductor chip 2000 is not limited to any type of semiconductor chip, and in some example embodiments second semiconductor chip 2000 may include a memory chip, a logic chip, a processor chip such as a central processing unit (CPU) or a graphics processing unit (GPU), a sensor chip, a system on chip (SOC), or the like.

The semiconductor chip 2000 may be separately packaged with a encapsulant or the like to be disposed above or on the interposer substrate 3000 in the form of a semiconductor package.

The interposer substrate 3000 may connect the semiconductor package 1000 and the semiconductor chip 2000, and may compensate for a line width difference between the semiconductor package 1000, the semiconductor chip 2000, and the package substrate 4000.

The package substrate 4000 may be a substrate generally used in semiconductor packaging. The package substrate 4000 may include an insulating layer and a wiring layer.

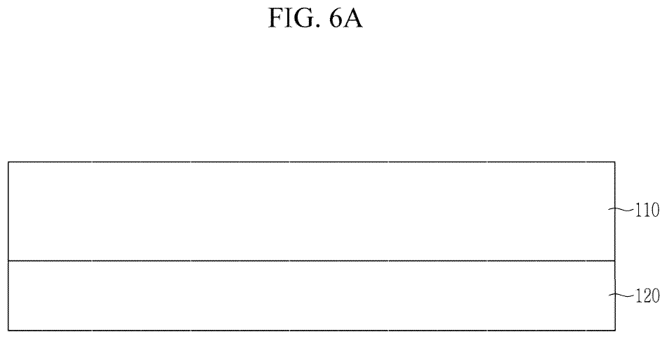

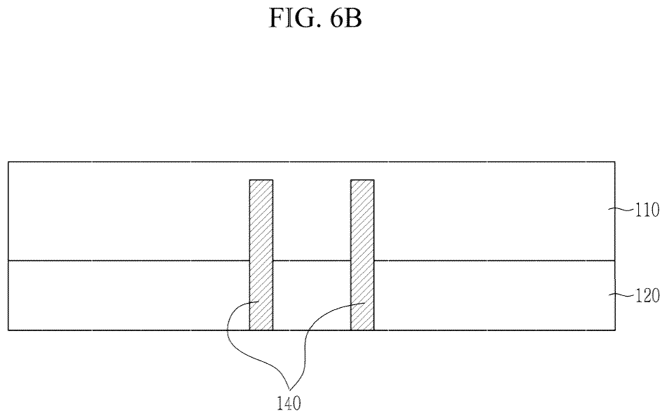

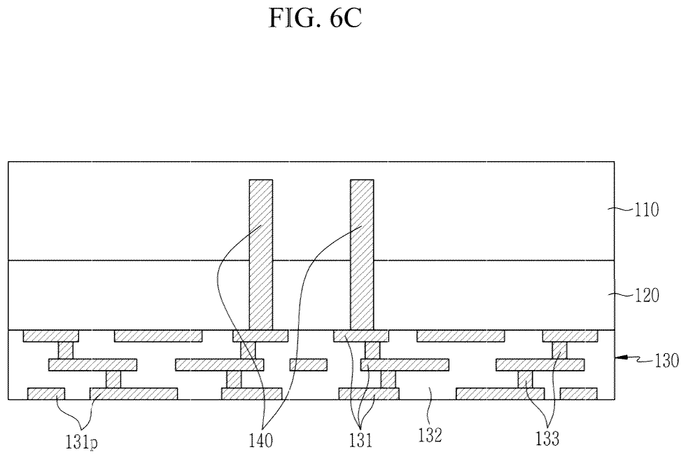

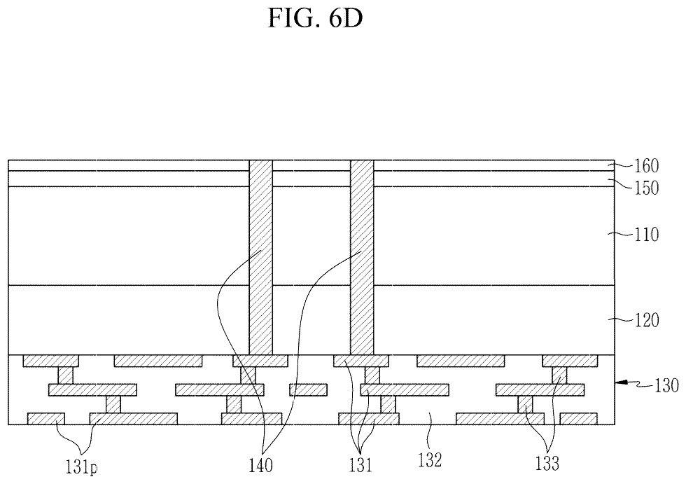

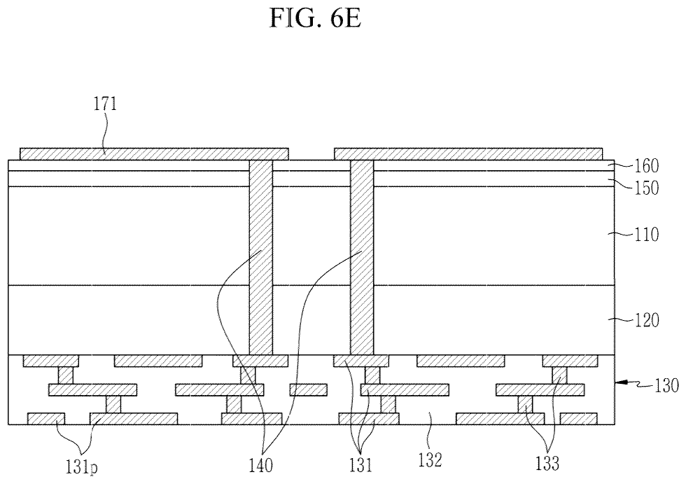

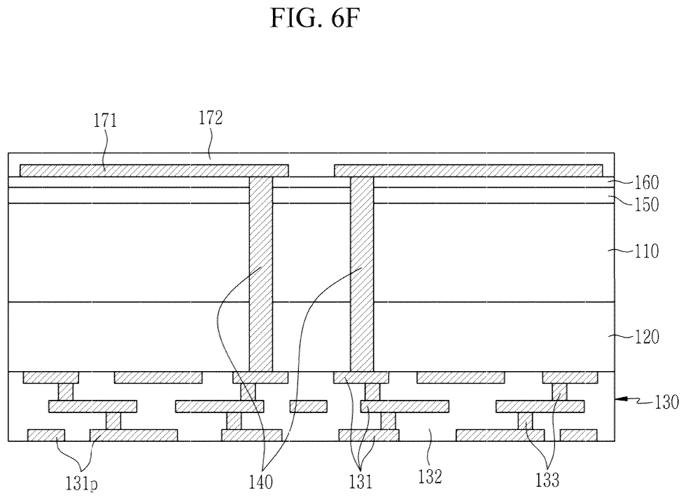

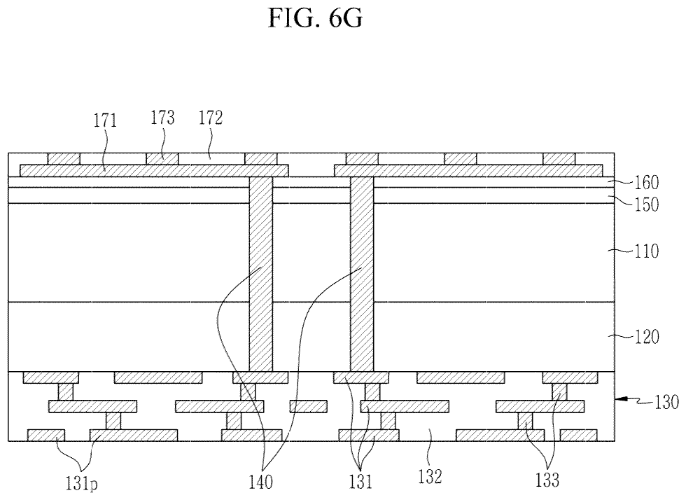

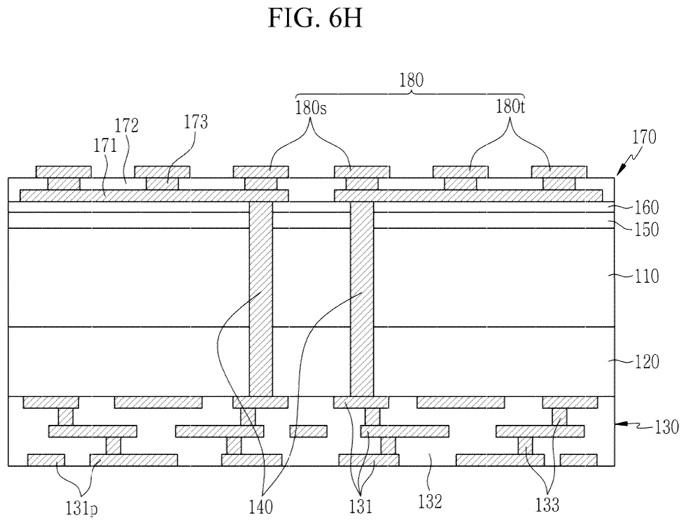

Hereinafter, a manufacturing process of the semiconductor chip according to some example embodiments of the inventive concepts will be briefly described with reference to FIGS. 6A-6H.

Referring to FIG. 6A, the element layer 120 is formed on the body 110. Before the element layer 120 is formed, an oxidation process of the body 110 may be performed.

Next, referring to FIG. 6B, the through via 140 is formed. For example, the through via 140 may be formed by forming a via hole, forming the conductive barrier film on a surface of a wall of the via hole, and then filling the inside of the via hole with the conductive plug. As described later, a portion of the body 110 may be removed to expose the through via 140, and one end of the through via may be buried in the body 110.

Next, referring to FIG. 6C, the wiring structure 130 is formed on the element layer 120. The wiring structure 130 may be formed to be connected to the through via 140. Additionally, the wiring structure 130 may be formed by sequentially repeating the wiring layer 131, the insulating layer 132, and the via 133.

However, a formation order of the element layer 120, the through via 140, and the wiring structure 130 may be different. For example, in some example embodiments the through via 140 may be first formed, and the element layer 120 and the wiring structure 130 may be later formed. As another example, the element layer 120 and the wiring structure 130 may be first formed, and the through via 140 may be later formed.

Next, referring to FIG. 6D, the first insulating layer 150 and the second insulating layer 160 are formed. Before the first insulating layer 150 and the second insulating layer 160 are formed, a portion of the body 110 may be removed through a chemical mechanical polishing (CMP) process or the like to expose the through via 140, and through this, the rear surface 110B of the body 110 may be formed.

The first insulating layer 150 and the second insulating layer 160 may be formed to cover a region of the through via 140 protruding from the rear surface of the body 110, and in order to expose the through via 140, a region of the first insulating layer 150 and the second insulating layer 160 covering the through via 140 may also be removed.

Next, referring to FIG. 6E, the conductive layer 171 connected to the through via 140 is formed. For example, the conductive layer 171 may be formed by forming a seed layer through a PVD process and forming a metal layer on the seed layer through electrolytic plating or the like.

Next, referring to FIG. 6F, the insulating layer 172 covering the conductive layer 171 is formed. The insulating layer 172 may be formed by a PVC process, a CVD process, a hardening process, and like depending on a material.

Next, referring to FIG. 6G, the via 173 that penetrates the insulating layer 172 is formed. For example, the via 173 may be formed by forming a via hole, forming a seed layer on a surface of a wall of the via hole, and then filling the inside of the via hole through electrolytic plating or the like.

Finally, referring to FIG. 6H, the signal pad 180s and the heat dissipation pad 180t connected to the via 173 are formed. For example, the signal pad 180s and the heat dissipation pad 180t may also be formed by forming a seed layer through a PVD process and forming a metal layer on the seed layer through electrolytic plating or the like.

While example embodiments of the inventive concepts have been described, it is to be understood that the inventive concepts are not limited to the disclosed example embodiments, but on the contrary, are intended to cover various modifications and equivalent arrangements included within the spirit and scope of the appended claims.

What is claimed is:

1. A semiconductor chip comprising:
a body having a front surface and a rear surface;
a wiring structure above the front surface of the body;
a through via penetrating the body, and the through via being connected to the wiring structure;
a heat dissipation structure above the rear surface of the body, and the heat dissipation structure including a conductive layer connected to the through via; and
a signal pad and at least one heat dissipation pad on the heat dissipation structure, and the signal pad and the heat dissipation pad being connected to the conductive layer.

2. The semiconductor chip of claim 1, wherein the signal pad includes at least one of a power pad and a ground pad.

3. The semiconductor chip of claim 1, wherein the conductive layer includes a metal layer.

4. The semiconductor chip of claim 1, wherein a thickness of the conductive layer is 3 to 5 μm.

5. The semiconductor chip of claim 1, wherein the conductive layer includes a conductive pattern overlapping the signal pad, the heat dissipation pad, and the through via on a plane.

6. The semiconductor chip of claim 1, wherein the heat dissipation structure further includes an insulating layer and vias,
the insulating layer covering the conductive layer, the vias penetrating the insulating layer, and the vias connecting the conductive layer to the signal pad and the at least one heat dissipation pad respectively.

7. The semiconductor chip of claim 6, wherein the insulating layer includes at least one of silicon oxide and silicon nitride.

8. The semiconductor chip of claim 6, wherein a thickness of the insulating layer is 3.5 to 6 μm.

9. The semiconductor chip of claim 6, wherein a diameter of the vias is 3 to 10 μm.

10. The semiconductor chip of claim 1, further comprising an insulating layer between the body and the conductive layer.

11. The semiconductor chip of claim 10, wherein the insulating layer is on the body,
the insulating layer including a first insulating layer and a second insulating layer, the first insulating layer including silicon oxide, and the second insulating layer including silicon nitride, and
the second insulating layer is between the first insulating layer and the heat dissipation structure.

12. The semiconductor chip of claim 1, wherein the semiconductor chip includes a memory chip.

13. The semiconductor chip of claim 1, wherein the at least one heat dissipation pad includes a plurality of heat dissipation pads spaced apart from each other.

14. A semiconductor package comprising:
a first semiconductor chip; and
a plurality of second semiconductor chips stacked on the first semiconductor chip,
wherein each of the plurality of second semiconductor chips includes
a body having a front surface and a rear surface,
a wiring structure above the front surface of the body,
a through via penetrating the body, and the through via being connected to the wiring structure,
a heat dissipation structure above the rear surface of the body, and the heat dissipation structure including a conductive layer connected to the through via, and
a signal pad and a heat dissipation pad on the heat dissipation structure, and the signal pad and the heat dissipation pad being connected to the conductive layer,
the first semiconductor chip including a memory controller chip, and the second semiconductor chip including a memory chip.

15. The semiconductor package of claim 14, wherein the signal pad includes at least one of a power pad and a ground pad.

16. The semiconductor package of claim 14, wherein the conductive layer includes a conductive pattern overlapping the signal pad, the heat dissipation pad, and the through via on a plane.

17. The semiconductor package of claim 14, wherein the heat dissipation structure further includes an insulating layer and vias,
the insulating layer covering the conductive layer, the vias penetrating the insulating layer, and the vias connecting the conductive layer to the signal pad and the heat dissipation pad respectively.

18. The semiconductor package of claim 14, further comprising conductive bumps on the signal pad and the heat dissipation pad of each of the plurality of second semiconductor chips, the conductive bumps connecting the plurality of second semiconductor chips to each other.

19. The semiconductor package of claim 14, further comprising an encapsulant encapsulating the plurality of second semiconductor chips.

20. A semiconductor package comprising:
a first semiconductor chip; and
a second semiconductor chip on the first semiconductor chip,
wherein the first semiconductor chip includes
a body having a front surface and a rear surface,
a wiring structure above the front surface of the body,
a through via penetrating the body, and the through via being connected to the wiring structure,
a heat dissipation structure above the rear surface of the body, and the heat dissipation structure including a conductive layer connected to the through via, and
a signal pad and a heat dissipation pad on the heat dissipation structure, and the signal pad and the heat dissipation pad being connected to the conductive layer.
